(19) United States
(12) Patent Application Publication
(10) Pub. No.: US 2007/0040196 A1
(43) Pub. Date: Feb. 22, 2007

(54) Semiconductor device and manufacturing method thereof, and thin film device

(75) Inventor: Osamu Matsuura, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 11/504,115

(22) Filed: Aug. 15, 2006

Related U.S. Application Data
(63) Continuation-in-part of application No. 11/358,077, filed on Feb. 22, 2006.

(30) Foreign Application Priority Data
Aug. 17, 2005 (JP) 2005-236935
Aug. 1, 2006 (JP) 2006-209930

(51) Int. Cl. H01L 29/94

(52) U.S. Cl. 257/295

(57) ABSTRACT

A manufacturing method of a semiconductor device is disclosed. The manufacturing method includes the steps of forming a contact plug in an insulation film so as to be connected to an element on a semiconductor substrate, applying PLA pretreatment to the insulation film in an NH₃ atmosphere, forming a Ti film over the contact plug, nitriding the Ti film to form a TiN film as a part of a lower electrode of a capacitor, and forming a metal film as another part of the lower electrode of the capacitor on the titanium nitride film.

### CROSS-REFERENCE TO RELATED APPLICATIONS

This application is a continuation in part of U.S. application Ser. No. 11/358,077 filed Feb. 22, 2006. This application is also based upon and claims the benefit of the earlier filing dates of Japanese Patent Application Nos. 2005-236935 and 2006-209930, filed in Aug. 17, 2005 and Aug. 1, 2006, respectively, the contents of which are incorporated herein by reference.

### BACKGROUND OF THE INVENTION

1. Field of the Invention

The present invention generally relates to a semiconductor device and a manufacturing method thereof in which a ferroelectric capacitor is formed, and a thin film device which needs excellent orientation.

2. Description of the Related Art

DRAM (dynamic random access memory) and SRAM (static RAM) known as volatile memories, and FLASH memory known as a non-volatile memory have been used in various fields. On the other hand, as memory which has both the high-speed low-voltage operability of DRAM and the non-volatile property of FLASH, FRAM (ferroelectric RAM), MRAM (magnetic RAM), and PRAM (programmable RAM) have potential, and various research and development efforts have been made of these devices. In fact, some of them have been mass-produced.

FRAM is a non-volatile memory making use of the hysteresis of a ferroelectric material. A semiconductor device comprising a FRAM has a capacitor structure in which an upper electrode, a ferroelectric layer, and a lower electrode are disposed on a substrate. As a ferroelectric material for the ferroelectric layer, Pb(Zr,Ti)O₃ [PZT] has large spontaneous polarization and has great potential. To form a ferroelectric layer, a CVD (chemical vapor deposition) method is suitable because of the need to form a dense film.

One of the technological issues regarding the ferroelectric capacitor is to increase capacity by making its structure fine. For miniaturization of the device structure, several methods are being considered, such as, employing a 1T1C (one transistor and one capacitor) circuit structure in place of a 2T2C (two transistors and two capacitors) circuit structure, employing a stack structure in place of a planar structure, and employing a three-dimensional structure in place of a flat structure.

To change the structure from a planar structure to a stack structure, it is necessary to form a lower electrode right above a transistor via a plug. In order to prevent oxidization of the plug, the lower electrode itself must have an oxygen barrier property. Further, in order for the PZT to have large spontaneous polarization, the PZT itself must have excellent orientation and crystal quality. In order to achieve this, the lower electrode positioned under the ferroelectric layer (PZT layer) also must have excellent orientation and crystal quality.

To obtain excellent orientation in the ferroelectric capacitor, it is proposed to perform PLA (plasma annealing) on a SiO2/Si substrate in an NH₃ atmosphere prior to forming a lower electrode, and then, to form a Ti film. (See, for example, Japanese Laid-Open Patent Publication No. 2004-153031.) A lower electrode made of Ir and so on is formed on the Ti film. However, the Ti itself becomes TiOx having an insulating property in a high temperature oxygen atmosphere. For this reason, when the Ti film is used on the plug, electric contact between the capacitor and the plug cannot be obtained.

Meanwhile, to prevent oxidization between the lower electrode of the capacitor and the plug, it is proposed to form a cavity by removing the uppermost end of a metal plug filling in a contact hole and to form a conductive film, such as a TiN film, in the cavity by sputtering, thereby forming a plug having a high oxidization preventing effect. (See, for example, Japanese Laid-Open Patent Publication No. 2001-284548.) However, in this method, a plug having a TiN film on the uppermost position comes into contact with an Ir/IrO₂ lower electrode.

Further, as a method for ensuring good electric characteristics of a ferroelectric capacitor, it is proposed to form a contact plug itself using TiN by vapor deposition and to form a lower electrode made of IrO₂ on the contact plug. (See, for example, Japanese Laid-Open Patent Publication No. 2000-114482).

However, with the above-described conventional methods aiming to prevent the oxidization, crystal orientation of the capacitor is not considered at all.

When a Ti film is formed after the PLA process, the crystal quality becomes good, and the orientation of the ferroelectric material of a capacitor can be well maintained. However, electric contact between the plug and the capacitor cannot be sufficiently obtained due to not sufficiently preventing oxidization.

If a TiN film deposited by sputtering or vapor deposition is inserted between a plug and a capacitor, oxidization is sufficiently prevented; however, satisfactory crystal quality cannot be obtained.

### SUMMARY OF THE INVENTION

Accordingly, the present invention may provide a semiconductor device with a ferroelectric capacitor with satisfactory electric characteristics, which device can simultaneously provide good crystal quality and sufficiently prevent oxidization. The invention may also provide a method of manufacturing such a semiconductor device. Further, there is provided a thin film device that requires excellent orientation.

According to an embodiment of the present invention, instead of depositing a titanium nitride (TiN) film by sputtering or vapor deposition, a titanium (Ti) film is formed first, and then the titanium film is nitrided by, for example, RTA (rapid thermal annealing) in a nitrogen-containing atmosphere to form a TiN film. With this method, the crystal quality of the titanium nitride film can be improved, while maintaining the oxygen barrier property.

In a more preferred example, the Ti film is formed after PLA (plasma annealing) pretreatment is performed on the wafer. Then, the Ti film is nitrided through the annealing in the nitrogen atmosphere to form the TiN film. With this method, a TiN film with more excellent crystal quality can be obtained, as compared with the TiN film obtained by nitriding a Ti film without PLA pretreatment.

Specifically, according to a first aspect of the present invention, there is provided a semiconductor device. The semiconductor device includes a capacitor having a titanium nitride (TiN) film as a part of a lower electrode. The titanium nitride film is obtained by nitriding a titanium (Ti) film formed after applying a PLA process.

Preferably, the FWHM (full width half maximum) of the (111) face of the titanium nitride film at a peak in an XRD (X-ray diffraction) pattern measured by a rocking curve method is in a range of 2° to 7°.

More preferably, the FWHM at the peak is in a range of 3° to 5°.

According to a second aspect of the present invention, there is provided a thin film device. The thin film device includes a semiconductor substrate, a titanium nitride film on the semiconductor substrate, and an orientation film on the titanium nitride film. In the thin film device, the FWHM at a peak on the (111) face in an XRD pattern measured by a rocking curve method of the titanium nitride film is in a range of 2° to 7°. More preferably, the FWHM at the peak is in a range of 3° to 5°.

The orientation film includes a metal thin film, a dielectric thin film, a piezoelectric thin film, a conductive nitride film, a conductive oxide film, or a ferroelectric thin film. When the orientation film is a metal thin film such as an Ir film or a Pt film, or a conductive nitride film such as a TiAlN film, the dielectric thin film, the piezoelectric thin film, and/or the ferroelectric thin film can be formed on the orientation film.

According to a third aspect of the present invention, there is provided a manufacturing method of a semiconductor device. The manufacturing method of the semiconductor device includes the steps of forming a contact plug in an insulation film so as to be connected to an element on a semiconductor substrate, applying a PLA (plasma annealing) process to the insulation film in an NH₃ atmosphere, forming a titanium film on the contact plug, nitriding the titanium film to form a titanium nitride film as a part of a lower electrode of a capacitor, and forming a metal film as another part of the lower electrode of the capacitor on the titanium nitride film.

In a preferred example, the PLA (plasma annealing) pretreatment is performed for 5 seconds or more, and more preferably, in a range from 5 seconds to 240 seconds. By performing the PLA process prior to the formation of the Ti film, the FWHM at the peak of the TiN (111) face measured by a rocking curve method can be converged to the range of 3° to 5°, and the FWHM at the peak of the (111) face of the lower electrode metal can be converged to the range of 2° to 3°.

By using the TiN film obtained through the above-described method as a part of the lower electrode of a ferroelectric capacitor, the electric characteristics of the ferroelectric capacitor can be improved to a great degree.

### BRIEF DESCRIPTION OF THE DRAWINGS

Other objects and further features of the present invention will be apparent from the following detailed description when read in conjunction with the accompanying drawings, in which:

FIG. 1A is a graph showing XRD (X-ray diffraction) patterns of lower electrode films of five types including an embodiment of the present invention;

FIG. 1B is a graph in which a peak part of the graph shown in FIG. 1A is enlarged;

FIG. 2A is a graph of TiN (111) face peak patterns measured by a rocking curve method, which TiN material is used as a part of the lower electrode;

FIG. 2B is a graph of the Ir (111) face peak patterns measured by a rocking curve method, which Ir material is used as another part of the lower electrode;

FIG. 3A is a table showing measured results of FWHMs (full width half maximums) at the (111) faces of a TiN film and an Ir film that are the elements of the lower electrode;

FIG. 3B is a graph showing the FWHMs at the (111) faces of TiN and Ir as a function of PLA time;

FIG. 4A is a diagram showing a first process for forming the semiconductor device according to the embodiment of the present invention;

FIG. 4B is a diagram showing a second process for forming the semiconductor device according to the embodiment of the present invention;

FIG. 4C is a diagram showing a third process for forming the semiconductor device according to the embodiment of the present invention;

FIG. 4D is a diagram showing a fourth process for forming the semiconductor device according to the embodiment of the present invention;

FIG. 4E is a diagram showing a fifth process for forming the semiconductor device according to the embodiment of the present invention;

FIG. 4F is a diagram showing a sixth process for forming the semiconductor device according to the embodiment of the present invention;

FIG. 4G is a diagram showing a seventh process for forming the semiconductor device according to the embodiment of the present invention; and

FIG. 5 is a flowchart showing processes of forming a ferroelectric capacitor in a manufacturing method of the semiconductor device according to the embodiment of the present invention.

### DESCRIPTION OF THE PREFERRED EMBODIMENT

Referring to the drawings, an embodiment of the present invention is explained.

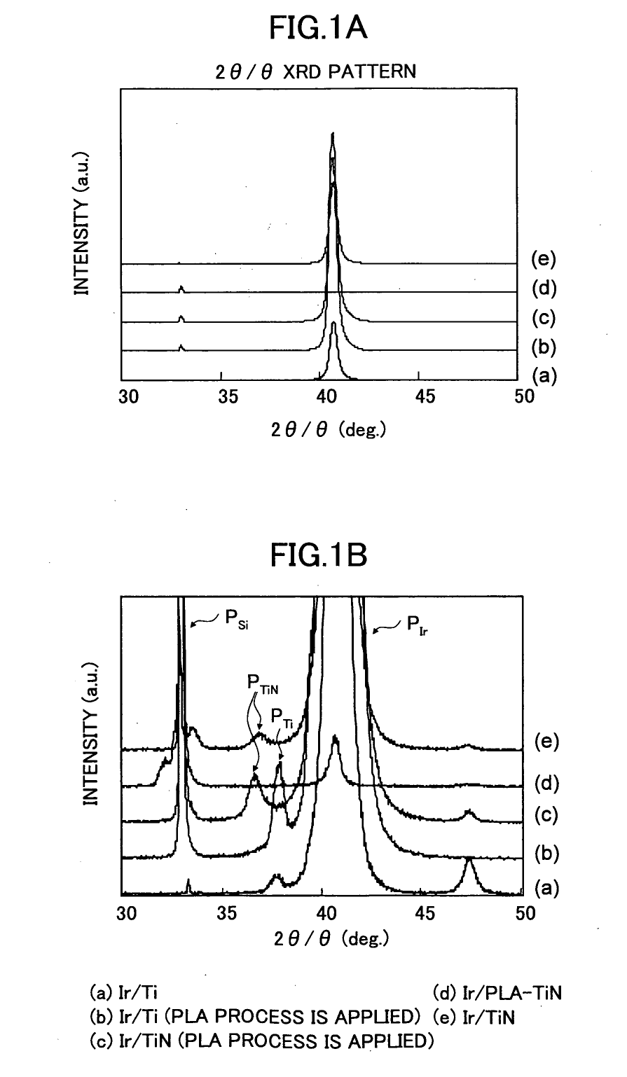

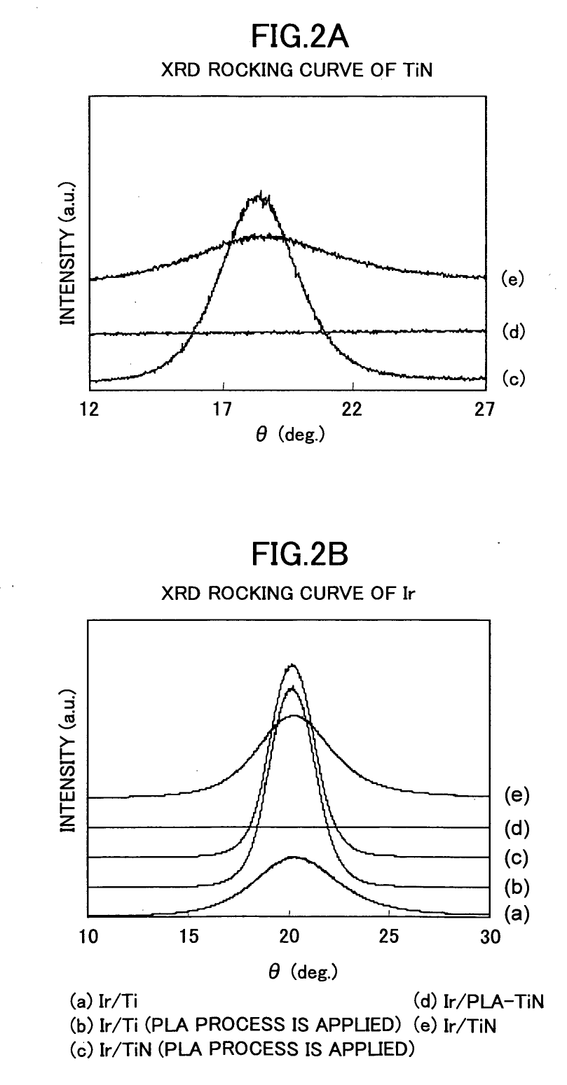

First, referring to FIGS. 1A, 1B, 2A, and 2B, the basic principle of the present invention is explained. In FIGS. 1A through 2B, characteristics of a lower electrode according to the embodiment of the present invention, in comparison with lower electrodes formed by conventional technologies, are shown. FIG. 1A is a graph showing XRD (X-ray diffraction) patterns of lower electrode films of five types including the embodiment of the present invention. FIG. 1B is a graph in which a peak part of the graph shown in FIG. 1A is enlarged. FIG. 2A is a graph showing rocking curves of TiN films formed as the lower electrode film by different methods. FIG. 2B is a graph showing rocking curves of Ir films formed as the lower electrode film.

In FIGS. 1A and 1B, five types of lower electrode samples are formed on a SiO2/Si substrate and an XRD pattern of each of the samples is measured by a 2θ/θ method. The measurement is performed on the (111) face of the lower electrode films (thin films).

In FIGS. 1A and 1B, a pattern (a) is an XRD pattern of an Ir/Ti sample, in which sample a Ti film is formed on a SiO2/Si substrate without performing PLA pretreatment and an Ir film is formed thereon using an existing technology.

In FIGS. 1A and 1B, a pattern (b) is an XRD pattern of an Ir/Ti sample in which a Ti film is formed on a SiO2/Si substrate after applying the PLA process and an Ir film is formed thereon by a known technology (refer to Patent Document 1).

In FIGS. 1A and 1B, a pattern (c) is an XRD pattern of an Ir/TiN sample used as a lower electrode film in the embodiment of the present invention, in which sample a Ti film is formed on the SiO2/Si substrate after applying the PLA process, then RTA (rapid thermal annealing) is performed on the Ti film in a nitrogen atmosphere to nitride the Ti film into becoming the TiN film, and an Ir film is formed on the TiN film.

In FIGS. 1A and 1B, a pattern (d) is an XRD pattern of an Ir/PLA-TiN sample, in which sample a TiN film is directly deposited over the SiO2/Si substrate by sputtering or vapor deposition, after applying the PLA process, and an Ir film is formed thereon. This is a comparison example.

In FIGS. 1A and 1B, a pattern (e) is an XRD pattern of an Ir/TiN sample used as an lower electrode film in the embodiment of the present invention, in which sample a Ti film is formed without performing the PLA process prior to the formation of the Ti film, the Ti film is nitrided by RTA in the nitrogen atmosphere to form a TiN film, and an Ir film is formed thereon.

In FIG. 1B, the patterns (c) and (e) have a peak P_{TiN} of TiN between the silicon peak Pₛᵢ and the iridium peak P_{Ir}, and the pattern (b) shows a peak P_{Ti} of Ti.

FIG. 2A is a graph showing the peak patterns of TiN (111) face of several samples measured by a rocking curve method, and FIG. 2B is a graph showing the peak patterns of Ir (111) faces of several samples measured by a rocking curve method. The peak patterns (a) through (e) shown in FIGS. 2A and 2B are obtained from the same samples explained in conjunction with the XRD patterns (a) through (e) of FIGS. 1A and 1B. As shown in FIGS. 2A and 2B, in the pattern (d), in which the TiN film itself is deposited over the SiO2/Si substrate by the sputtering process or the vapor deposition process after application of the PLA process, and the Ir film is then formed thereon, neither a peak of the TiN film nor a peak of the Ir film is observed, and it is understandable that the crystal orientation is less than satisfactory. That is, if a TiN film is directly deposited in the fabrication process of a device requiring excellent orientation, for example, a ferroelectric capacitor, a piezoelectric element, a liquid crystal element, and so on, the device does not function well.

On the other hand, pattern (c) is measured from the sample of the embodiment, in which sample a Ti film is formed on the SiO2/Si substrate after applying the PLA process, then RTA is performed on the Ti film in a nitrogen atmosphere to form a TiN film, and an Ir film is formed thereon. The TiN film shows a clear peak (refer to FIG. 2A) and also the Ir film formed on the TiN film shows a sharp peak (refer to FIG. 2B). The orientation of a ferroelectric film formed on the above lower electrode is greatly improved and a ferroelectric capacitor formed by the ferroelectric film shows an excellent polarization characteristic.

Similarly, in the pattern (e) of the embodiment of the present invention, in which a Ti film is formed without applying the PLA pretreatment, is nitrided by RTA in a nitrogen atmosphere to form a TiN film, and an Ir film is formed thereon, the TiN film shows a gentle peak (refer to FIG. 2A). However, comparing the TiN film of pattern (e) with the TiN film of pattern (d) directly formed by sputtering, both the TiN film and the Ir film in pattern (e) show good crystal quality (refer to FIGS. 2A and 2B).

As shown in FIG. 2B, in the pattern (b) by an existing technology in which a Ti film is formed over a SiO2/Si substrate after applying the PLA process and an Ir film is formed thereon, the Ir film shows an excellent peak, and with this, the Ir film shows excellent crystal quality as a lower electrode. However, as described above, the Ti film is easily oxidized and does not function as an oxygen barrier film.

Returning to FIG. 1B, in comparison between the patterns (c) and (e) in the embodiment of the present invention, the XRD peak position of the TiN film obtained by nitriding the Ti film deposited without applying the PLA pretreatment (pattern (e)) is shifted from that of the pattern (c), and the peak (P_{TiN}) of the pattern (e) is duller than that of the pattern (c). Because in the XRD pattern the peak position varies depending on the lattice constant, it can be said that the lattice constant of the TiN film nitrided without applying the PLA process (pattern (e)) deviates from the original lattice constant of TiN. That is, that TiN film is not completely nitrided. Thus, it is understood that the PLA process before forming the Ti film enhances the nitriding of Ti.

Both of the patterns (c) and (e) of the lower electrode in the embodiment of the present invention indicate excellent film crystal quality and an oxygen barrier property. However, the pattern (c) having the PLA process applied indicates a more excellent film crystal quality (orientation).

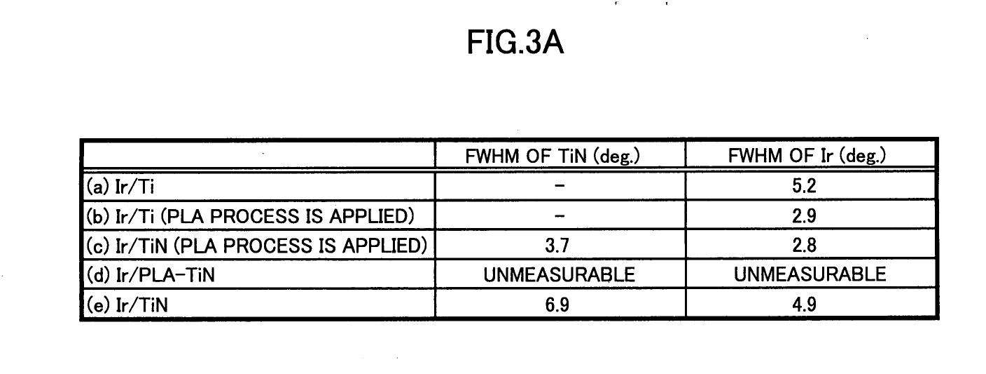

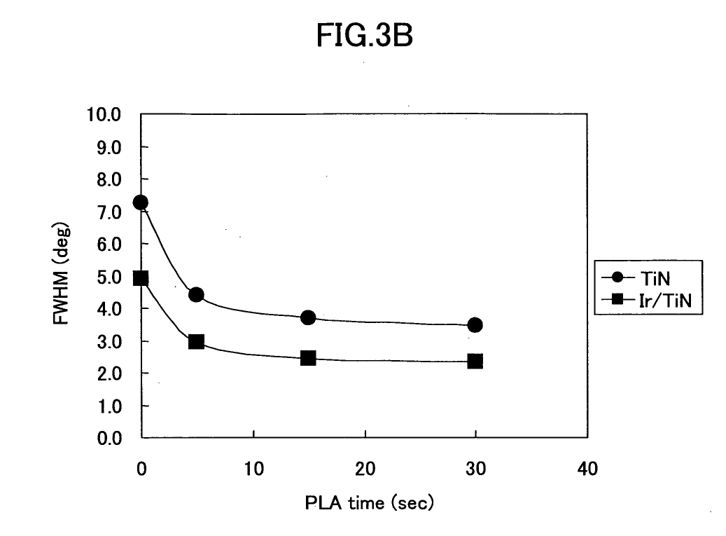

FIG. 3A is a table showing measured results of FWHMs (full width half maximums) of the peaks of the above five patterns (a) through (e) shown in FIGS. 1A through 2B. In FIG. 3, the FWHM of the Ir film and the FWHM of the TiN film, which films are elements of the lower electrode, are shown.

In the TiN film directly deposited by a sputtering process and so on (pattern (d)), the peak itself does not exist and the FWHM cannot be measured.

In the pattern (a) from the sample in which the Ir film is formed over the Ti film by an existing technology, the FWHM of the Ir film is over 5°, and there is less contribution to improving the orientation of a ferroelectric material. In addition, the Ti film has a low oxygen barrier property.

In the pattern (b) from the sample in which a Ti film is formed after the PLA process and an Ir film is formed thereon by an existing technology, the FWHM of the Ir (111) face is 2.9°, which value is excellent. However, similar to the pattern (a), the Ti film has a low oxygen barrier property.

In the pattern (c) of the embodiment of the present invention, in which a Ti (111) film is formed after the PLA process, is nitrided by RTA in a nitrogen atmosphere, and an Ir film is formed on the TiN film, the FWHM of the Ir (111) face is 2.8°, and the FWHM of the TiN (111) face is 3.7°. These measurement results show excellent crystal quality. The orientation of a ferroelectric film formed on the above lower electrode film is improved and a capacitor is able to have an excellent polarization characteristic. The FWHM of the TiN film can be made as small as approximate 2° when tuned by a PLA process.

In the pattern (e) of the embodiment of the present invention, in which a Ti film is formed on a SiO2/Si substrate without applying the PLA pretreatment, is nitrided by RTA in a nitrogen atmosphere to form the TiN film, and an Ir film is formed thereon, the FWHM of the Ir (111) face is 4.9°, and the FWHM of the TiN (111) face is 6.9°.

FIG. 3B is a graph of FWHMs of a TiN film and an Ir film over the TiN film, as a function of PLA time. As indicated by the Table shown in FIG. 3A, the FWHM of the TiN (111) face without PLA pretreatment is 6.9°; however, the FWHM can be reduced by performing the PLA pretreatment, and by increasing the PLA time. To be more precise, by performing the PLA pretreatment for 5 seconds or longer, the FWHM of the TIN (111) face can be converged to the range from 3° to 5°, and the FWHM of the Ir/TiN (Ir (111) face over TiN film) can be converged to the range from 2° to 3°.

As supported by the data, when the TiN film having an XRD FWHM ranging from 2° to 7°, preferably, 3° to 5°, is used for a part of the lower electrode, a satisfactory oxygen barrier property and good crystal quality can be obtained. In this case, the XRD FWHM of the Ir film formed over the TiN film is 2° to 5°, preferably, 2° to 3°.

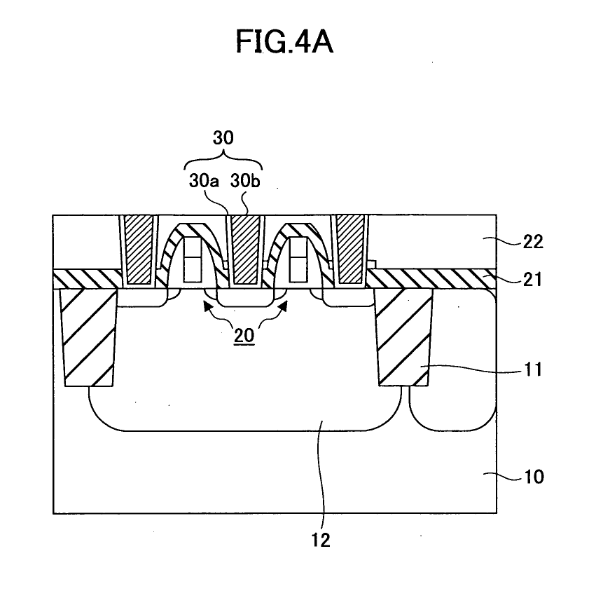

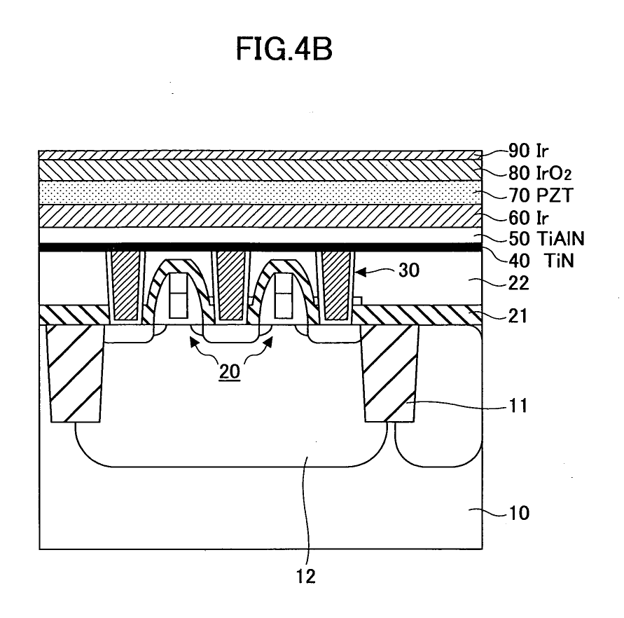

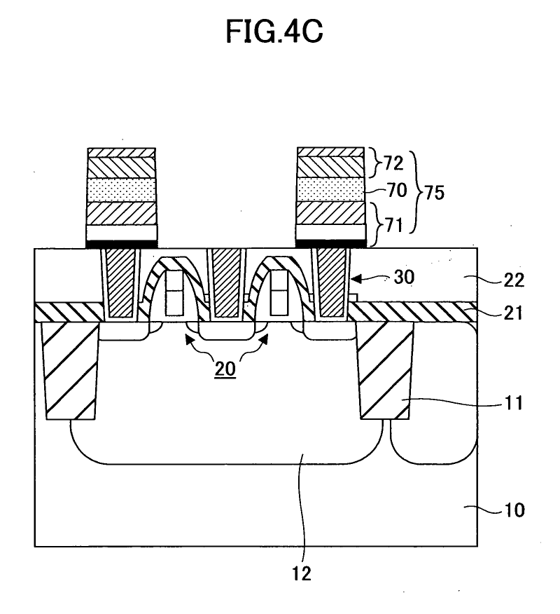

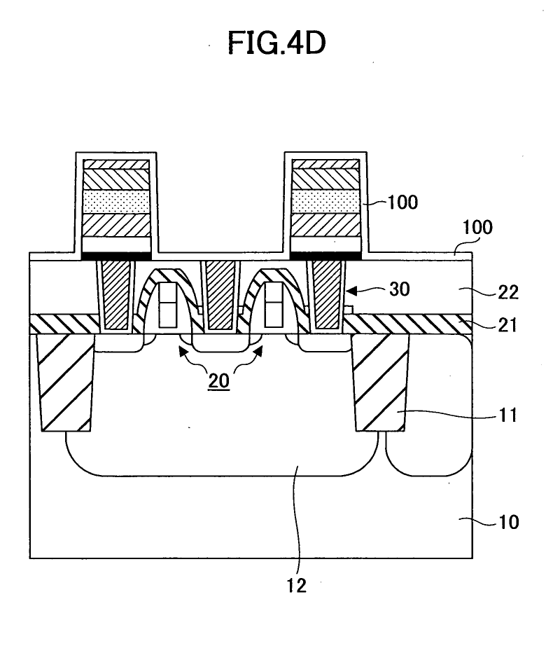

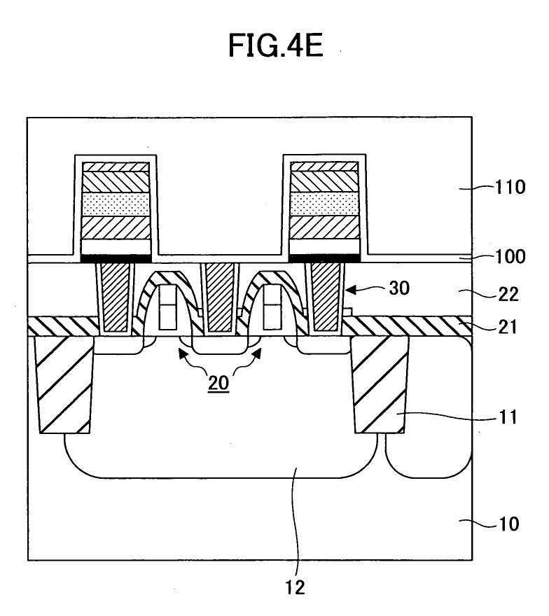

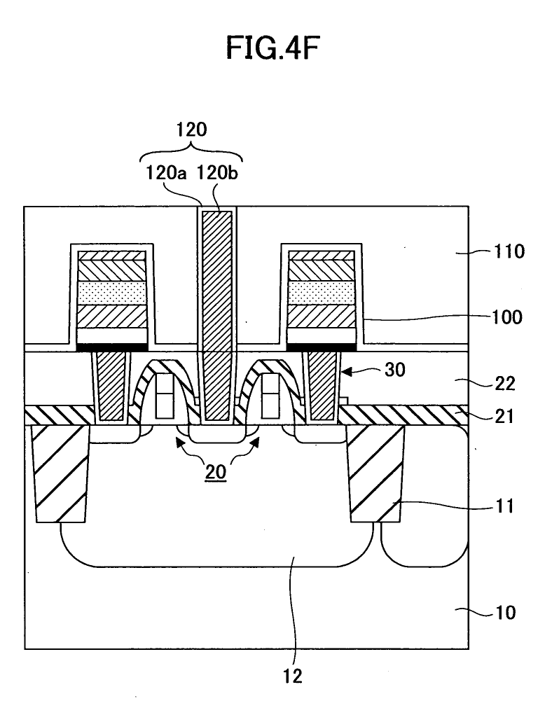

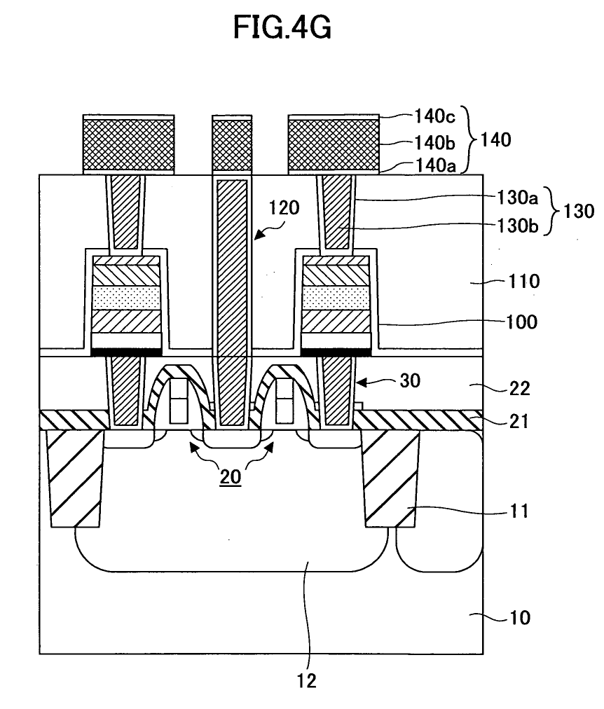

FIGS. 4A through 4G are diagrams showing processes for manufacturing a semiconductor device in which the above TiN film is used for a part of a lower electrode of a capacitor.

As shown in FIG. 4A, first, MOS transistors 20 are formed in a well region 12 isolated by isolation regions 11 on a substrate 10 by an existing method. A cover insulating film 21 (for example, SiON film) for protecting the MOS transistors 20 is formed, a first dielectric inter layer 22 is deposited and a contact plug 30 reaching an impurity diffusion region (source and drain) of the MOS transistors 20 is formed. In forming the contact plug 30, for example, a TiN/Ti glue layer 30a is formed in a contact hole (not shown) opened in the first dielectric inter layer 22 by sputtering, a tungsten (W) layer 30b is deposited by a CVD (chemical vapor deposition) method, and after this, a CMP (chemical mechanical polishing) process is applied and the face is flattened.

Next, as shown in FIG. 4B, lower electrode films 40, 50, and 60, a ferroelectric film 70, and upper electrode films 80 and 90 are deposited on the entire face in this order. In the embodiment, thin films of the lower electrodes are a TiN film 40, a TiAlN film 50, and an Ir film 60. In more detail, in order to make the orientation high, a Ti film whose thickness is 20 nm is formed, and the TiN film 40 is formed by applying an RTA process to the Ti film in an N₂ atmosphere (flow rate is 10 slm) at 650° C. for two minutes. That is, the Ti film is nitrided and the TiN film 40 is formed.

Preferably, prior to forming the Ti film, PLA pretreatment is performed in an NH₃ atmosphere. The PLA conditions in this example are as follows: the substrate temperature is 400° C., the power of the high frequency power source of 13.56 MHz to be supplied to the substrate is 100 W, the power of the high frequency power source of 350 kHz to be supplied to the plasma generating region is 55 W, and the PLA time is 60 seconds. Next, the TiAlN film 50 serving as an oxygen barrier film whose thickness is 100 nm is formed, and the Ir film 60 serving as an electrode film whose thickness is 100 nm is formed by sputtering. Further, a PZT film that is a first layer whose thickness is 5 nm is deposited by a MOCVD (metal organic chemical vapor deposition) method, and a Pb(Zr,Ti)O₃[PZT] film whose thickness is 115 nm is sequentially formed on the first layer; with this, the ferroelectric film 70 is formed. At this stage, the substrate temperature is 620° C. and the pressure is 666 Pa (5 Torr). In addition, on the ferroelectric film 70, an IrO₂ film 80 whose thickness is 150 nm that is a part of an upper electrode film for a ferroelectric capacitor is formed by sputtering, and further, an Ir film 90 (a part of an upper electrode film) whose thickness is 50 nm is formed on the IrO₂ film 80. After this, in order to recover from damage to the ferroelectric film 70 caused by forming the upper electrode films 80 and 90, a recovery annealing process is applied. In the embodiment, a furnace annealing process is applied in an annealing furnace at 550° C. for 60 minutes in an O₂ atmosphere.

Next, as shown in FIG. 4C, a ferroelectric capacitor 75 having a stack structure which is formed by an upper electrode 72 (formed by the upper electrode films 90 and 80), the ferroelectric film 70, and a lower electrode 71 (formed by the lower electrode films 60, 50, and 40) is formed. In more detail, a predetermined hard mask (not shown) is formed by a photolithography method, and regions of the upper electrode films 90 and 80, the ferroelectric film 70, and the lower electrode films 60, 50, and 40 where the hard mask does not cover are sequentially removed by an etching process.

Next, as shown in FIG. 4D, an alumina protection film 100 is deposited, and furnace annealing is applied at 550° C. in an O₂ atmosphere for 60 minutes.

Next, as shown in FIG. 4E, a second dielectric inter layer 110 is formed and the face of the second dielectric inter layer 110 is flattened by a CMP process. In this case, the second dielectric inter layer 110 is an oxide film formed by using a HDP (high density plasma) instrument, and the thickness from the upper face of the Ir film 90 that is a part of the upper electrode of the ferroelectric capacitor 75 to the flattened face is 300 nm.

Next, as shown in FIG. 4F, a contact hole (not shown) reaching the contact plug 30 is formed by patterning and etching, a TiN film 120a that is a barrier metal or a glue layer and a W (tungsten) film 120b that is a contact metal are formed, and the face is flattened by a CMP process. With this, a contact plug 120 is formed.

Next, as shown in FIG. 4G, a contact hole (not shown) connecting to the upper electrode 72 of the ferroelectric capacitor 75 is formed, a TiN film 130a that is a barrier metal film and a W (tungsten) film 130b that is a contact metal film are formed in the contact hole, and the faces of the TiN film 130a and the W film 130b are flattened by a CMP process. With this, a contact plug 130 is formed. Further, a first layer metal wiring 140 is formed by TiN/Al/TiN films. The thickness of each film is as follows: for example, the thickness of a TiN film 140a is 70 nm, the thickness of an Al film 140b is 360 nm, and the thickness of a TiN film 140c is 50 nm. After forming the first layer metal wiring 140, an exposure process and an etching process are applied, and a multi layer wiring forming process is performed by forming a third dielectric inter layer (not shown).

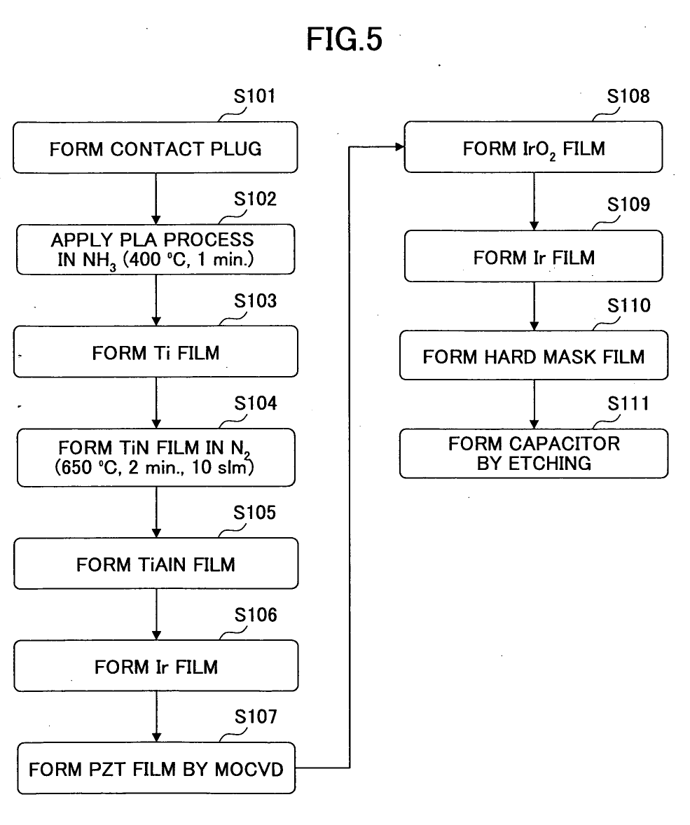

FIG. 5 is a flowchart showing processes of forming a ferroelectric capacitor in a manufacturing method of a semiconductor device according to the embodiment of the present invention.

Referring to the flowchart shown in FIG. 5, the processes are explained.

First, a contact plug 30 connecting to an impurity diffusion region of a MOS transistor 20 is formed (step S101). Next, a PLA process is applied in an NH₃ atmosphere at 400° C. for one minute (step S102). A Ti film is formed (step S103). After this, a TiN film 40 is formed by applying an RTA process to the Ti film in an N₂ atmosphere (10 slm) at 650° C. for two minutes (step S104). A TiAlN film 50 is formed (step S105), and an Ir film 60 is formed (step S106). Further, a PZT film that is a ferroelectric film is formed by a MOCVD method (step S107), and an IrO₂ film 80 and an Ir film 90 that are elements of an upper electrode are sequentially formed (steps S108 and S109).

Next, a hard mask is formed by stacking, for example, a TiN film and a TEOS (tetra ethyl ortho silicate) film, and patterning with a predetermined pattern (step S110). A ferroelectric capacitor 75 having a predetermined shape is formed by etching the Ir film 90, the IrO₂ film 80, the ferroelectric film 70, the Ir film 60, the TiAlN film 50, and the TiN film 40 with the use of the hard mask (step S111).

Although the present invention is described based on specific examples, the present invention is not limited to these embodiments. For example, the present invention can be applied to a stack structure or a planar structure in which a material such as Pt is used as the lower electrode. In the embodiment of the present invention, the ferroelectric film is formed by sputtering or MOCVD; however, other suitable film formation methods, such as a spin-on method or a sol-gel method can be used. Further, other suitable ferroelectric materials may be used. In addition, variations and modifications may be made without departing from the scope of the present invention.

Because the TiN film of the embodiment of the present invention is highly oriented to the (111) direction, it can be applied to various types of capacitor structures as long as a material that reflects the orientation of the underlying layer is used in the capacitor structure. In addition, the TiN film can be used as a conductive film in various devices which require good orientation and the oxygen barrier property.

The TiN film of the embodiment of the present invention can also be used in thin film devices, including a piezoelectric device and a liquid crystal device which require good orientation. In such thin film devices, an orientation film may be formed over a TiN film with XRD FWHM of 2° to 7°, preferably, 3° to 5° at the peak on the (111) face, measured by the rocking curve method.

The orientation film is, for example, a metal thin film made of Ir, Pt, and so on, a conductive nitride film such as a TiAlN film, a conductive oxide film, a dielectric thin film, a piezoelectric thin film, and a ferroelectric thin film. If an Ir film, a Pt film, or a TiAlN film is used as the orientation film, another thin film, such as a dielectric thin film, a piezoelectric thin film, or a ferroelectric thin film may be formed over the orientation film.

In any one of the above cases, the combination of the PLA pretreatment and the nitriding of the Ti film can produce a TiN film with high orientation and a satisfactory oxygen barrier property. In this case, the orientation of the film formed over the TiN film can also be improved, reflecting the high orientation of the underlying TiN film.

What is claimed is:

1. A semiconductor device, comprising:
a capacitor having a titanium nitride film as a part of a lower electrode, wherein:
the titanium nitride film is obtained through nitriding a titanium film formed after a plasma annealing pretreatment.

2. A semiconductor device, comprising:
a capacitor having a titanium nitride film as a part of a lower electrode, wherein:
a FWHM (full width half maximum) of the (111) face of the titanium nitride film at a peak in an XRD (X-ray diffraction) pattern measured by a rocking curve method is in a range of 2° to 7°.

3. The semiconductor device as claimed in claim 2, wherein:
the FWHM at the peak is in a range of 3° to 5°.

4. The semiconductor device as claimed in claim 2, further comprising:
a metal film on the titanium nitride film, the metal film being a part of the lower electrode, wherein:
a FWHM of the (111) face of the metal film at a peak in an XRD pattern measured by a rocking curve method is in a range of 2° to 5°.

5. The semiconductor device as claimed in claim 3, further comprising:
a metal film on the titanium nitride film as a part of the lower electrode, wherein:
a FWHM of the (111) face of the metal film at a peak in an XRD pattern measured by a rocking curve method is in a range of 2° to 3°.

6. The semiconductor device as claimed in claim 4, further comprising:
an oxygen barrier film between the titanium nitride film and the metal film.

7. The semiconductor device as claimed in claim 5, further comprising:
an oxygen barrier film between the titanium nitride film and the metal film.

8. A thin film device, comprising:
a semiconductor substrate;
a titanium nitride film on the semiconductor substrate; and
an orientation film on the titanium nitride film; wherein:
a FWHM of the (111) face of the titanium nitride film at a peak in an XRD pattern measured by a rocking curve method is in a range of 2° to 7°.

9. The thin film device as claimed in claim 8, wherein:
the FWHM of the (111) face of the titanium nitride film is in a range of 3° to 5°.

10. The thin film device as claimed in claim 8, wherein:
the orientation film includes an Ir film, a Pt film, and a TiAlN film.

11. The thin film device as claimed in claim 8, further comprising:
a dielectric thin film, a piezoelectric thin film, and/or a ferroelectric thin film formed on the orientation film.

12. A manufacturing method of a semiconductor device, comprising the steps of:
forming a contact plug in an insulation film so as to be connected to an element on a semiconductor substrate;
applying a PLA pretreatment to the insulation film in an NH₃ atmosphere;
forming a titanium film on the contact plug;
nitriding the titanium film to form a titanium nitride film as a part of a lower electrode of a capacitor; and
forming a metal film as another part of the lower electrode of the capacitor on the titanium nitride film.

13. The manufacturing method of the semiconductor device as claimed in claim 12, wherein:
the nitriding step includes annealing the titanium film in the atmosphere containing nitrogen at 650° C. of semiconductor substrate temperature for two minutes.

14. The manufacturing method of the semiconductor device as claimed in claim 12, further comprising the step of:
forming an oxygen barrier film between the titanium nitride film and the metal film.

15. The manufacturing method of the semiconductor device as claimed in claim 12, further comprising the step of:
forming a ferroelectric capacitor by sequentially forming a ferroelectric film and an upper electrode film on the metal film.

16. The manufacturing method of the semiconductor device as claimed in claim 12, wherein the PLA pretreatment is performed for 5 seconds or longer.

17. The manufacturing method of the semiconductor device as claimed in claim 12, wherein the PLA pretreatment is performed for a predetermined period of time so as to converge the FWHM of the (111) face of the titanium nitride film at a peak in an XRD pattern measured by a rocking curve method to a range of 3° to 5° and converge the (111) face of the metal film at a peak in an XRD pattern measured by a rocking curve method to a range of 2° to 3°.
